(19) United States
(12) Patent Application Publication
(10) Pub. No.: US 2026/0255863 A1
(43) Pub. Date: Aug. 27, 2026

(54) DISPLAY DEVICE

(71) Applicant: LG Display Co., Ltd., Seoul (KR)

(72) Inventors: Hyungguen KIM, Paju-si (KR); Taewoon KO, Paju-si (KR); Jinhyung JUNG, Paju-si (KR)

(73) Assignee: LG Display Co., Ltd., Seoul (KR)

(21) Appl. No.: 19/548,154

(22) Filed: Feb. 24, 2026

(30) Foreign Application Priority Data
Feb. 25, 2025 (KR) 10-2025-0024362

(51) Int. Cl. H10K 59/80

(52) U.S. Cl. CPC H10K 59/8794; H10K 59/873

(57) ABSTRACT

Disclosed is a display device including a display panel having a cover layer, a device layer on the cover layer, and an encapsulation layer on the device layer. A source substrate is on the display panel, and at least one driver chip is on the source substrate. The encapsulation layer includes at least one trench formed by recessing a surface of the encapsulation layer. The at least one trench overlaps the at least one driver chip. The trench may contain air and may be positioned between adjacent protrusions of the encapsulation layer. The display device may further include at least one heat dissipation portion disposed on the driver chip, the heat dissipation portion having elasticity. The trench and protrusion structure is configured to influence heat transfer between the device layer, the driver chip, and an external side of the display device.

### CROSS-REFERENCE TO RELATED APPLICATION

The present application claims priority to Korea Patent Application No. 10-2025-0024362, filed Feb. 25, 2025, the entire contents of which is incorporated herein for all purposes by this reference.

### BACKGROUND

### Technical Field

The present disclosure relates to a display device.

### Description of the Related Art

With the development of an information-oriented society, various demands for display devices for displaying images have increased, and various types of display devices, such as liquid crystal display devices, and organic light emitting display devices have been used.

The display device includes a plurality of pixels, and a plurality of switching elements for driving and controlling the pixels.

### BRIEF SUMMARY

The present disclosure describes a thermally structured encapsulation layer that performs more than a sealing or protective function. The encapsulation layer includes trenches that overlap the driver chips, with air occupying the trenches to provide regions of very low thermal conductivity. These air regions restrict heat transfer toward the display panel. Between adjacent trenches, metal protrusions are formed to define controlled heat conduction paths. Through this configuration, heat generated in the device layer and the driver chips is intentionally redirected toward the rear of the display rather than diffusing upward into the panel.

The present disclosure further describes elastic heat dissipation portions disposed on (or in some cases, directly on) the driver chips and aligned with the protrusions of the encapsulation layer. These elastic members maintain conductive thermal contact while also absorbing mechanical shock from external impacts. This structure enables efficient heat transfer to the cover bottom without requiring rigid or thick heat spreaders, thereby supporting a reduced overall device thickness while improving mechanical reliability.

The disclosed configurations also allow thermal adjustment based on driver chip heat generation differences. The size, shape, or area ratio of the trenches and protrusions, as well as the number or placement of heat dissipation portions, may be varied depending on the heat output or size of individual driver chips. Hotter driver chips can be paired with larger trench regions to restrict heat transfer toward the panel, while cooler driver chips can maintain greater conductive coupling. This approach supports temperature uniformity across the display, improved thermal stability, and reduced power-related degradation of the device layer.

Various embodiments of the present disclosure provide a display device capable of improving a heat dissipation function.

Various embodiments of the present disclosure provide a display device capable of adjusting a travel path of dissipated heat.

Various embodiments of the present disclosure provide a display device capable of coping with an impact applied from the outside.

Various embodiments of the present disclosure provide a display device capable of improving a heat dissipation performance in consideration of a difference in a heat generation amount.

Various embodiments of the present disclosure provide a display device capable of adjusting a temperature balance among driver chips in consideration of a difference in a heat generation amount.

Various embodiments of the present disclosure provide a display device which is slim in terms of a thickness.

Various embodiments of the present disclosure provide a low-power display device.

The technical benefits of the present disclosure are not limited to the above benefits; other benefits may be inferred based on the following embodiments.

One embodiment is a display device, including: a display panel comprising a cover layer, a device layer on the cover layer, and an encapsulation layer on the device layer; a source substrate on the display panel; and at least one driver chip on the source substrate, and the encapsulation layer may include at least one trench configured to recess a surface of the encapsulation layer, and the at least one trench may overlap the driver chip.

Another embodiment is a display device, including: a display panel comprising a device layer and an encapsulation layer on the device layer; a source substrate on the display panel; and a source substrate portion comprising at least one driver chip on the source substrate; and a plurality of heat dissipation portions on the at least one driver chip, and the heat dissipation portion may have elasticity.

Other details of the embodiment is included in the detailed description and the accompanying drawings.

The display device according to embodiments of the present disclosure may improve a heat dissipation performance due to conduction as a path for dissipating heat generated on a device layer along a protrusion between trenches recessed in a trapezoidal shape and a heat dissipation portion overlapping the trenches is formed, and a heat dissipation amount of heat generated in the driver chip gets greater due to conduction generated in the heat dissipation portion, thereby improving a general heat dissipation performance of a display device.

The display device according to embodiments of the present disclosure may adjust to restrict a heat dissipation path because the display device may restrict heat generated from the driver chip from moving to the display panel due to inclusion of an air on the encapsulation layer and may change the heat dissipation path to be led in an opposite direction of the display panel.

The display device according to embodiments of the present disclosure may ease an impact generated when the heat dissipation portion and the cover bottom contact each other by an impact applied from the outside, because the heat dissipation portion of the display device according to embodiments of the present disclosure has elasticity.

The display device according to embodiments of the present disclosure may improve a heat dissipation performance of the display device by adjusting an arrangement of the encapsulation layer and the heat dissipation portion in consideration of the heat dissipation amount which varies according to a size of the driver chip.

The display device according to embodiments of the present disclosure may adjust a temperature of the driver chips uniformly by adjusting an arrangement of the encapsulation layer and the heat dissipation portion in consideration of the heat dissipation amount which varies according to a size of the driver chip.

The display device according to embodiments of the present disclosure may make the display device slim in terms of a thickness because the heat dissipation portion has elasticity.

The display device according to embodiments of the present disclosure may achieve a lower power by blocking heat proceeding to the device layer.

The effects of the present disclosure are not limited to the above-described effects and other effects which are not described herein may be derived by those skilled in the art from the following description of the embodiments of the present disclosure.

### BRIEF DESCRIPTION OF THE SEVERAL VIEWS OF THE DRAWINGS

FIG. 1 is a cross-sectional diagram of an embodiment of the present disclosure.

FIG. 2 is a plan diagram of a display device according to FIG. 1.

FIG. 3 is a diagram illustrating Q1 region in FIG. 2.

FIG. 4 is a perspective diagram illustrating Q1 region in FIG. 2.

FIG. 5 is a cross-sectional diagram taken along A-A′ line in FIG. 2.

FIG. 6 is a schematic diagram illustrating a travel path of heat in a display device according to an embodiment.

FIG. 7 is a schematic diagram illustrating a temperature gradient of a display device according to an embodiment.

FIG. 8 is a cross-sectional diagram of a display device according to another embodiment.

FIG. 9 is a schematic diagram illustrating a travel path of heat in a display device according to FIG. 8.

FIG. 10 is a cross-sectional diagram of a display device according to still another embodiment.

FIG. 11 is a schematic diagram illustrating a travel path of heat in a display device according to FIG. 10.

FIG. 12 is a cross-sectional diagram of a display device according to still another embodiment.

### DETAILED DESCRIPTION

Hereinafter, embodiments will be described in detail with reference to the accompanying drawings.

The same reference numbers will be used throughout the drawings to refer to the same or like parts.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

“And/or” includes all of one or more combinations defined by related components.

It will be understood that when the terms “first” and “second” are used herein to describe various components, these components should not be limited by these terms. The above terms are used only to distinguish one component from another. For example, a first component may be referred to as a second component and vice versa without departing from the scope of the present disclosure. Singular expressions and terms used herein also encompass or include plural expressions and terms, unless the context clearly indicates otherwise.

Spatially relative terms, such as “beneath,” “below,” “lower,” “above,” “upper” and the like, may be used herein for ease of description to describe one element or feature’s relationship to another element(s) or feature(s) as illustrated in the drawings. The above terms are relative concepts and are explained based on the directions indicated in the drawing. For example, there may be one or more other parts between two parts, unless “immediately” or “directly” is used. Spatially relative terms such as “below,” “beneath,” “lower,” “above,” and “upper” may be used to readily describe the relationship of one element or component to another, as illustrated in the drawings. Spatially relative terms should be understood to include different orientations of the element when in use or operation in addition to the orientations depicted in the drawings. For example, if elements depicted in a drawing are flipped, an element described as “below” or “beneath” another element may end up being placed “above” the other element. Thus, the exemplary term “below” can encompass both downward and upward directions.

In various embodiments of the disclosure, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, the display device of the present disclosure surveyed through the accompanying drawings and embodiments is as below.

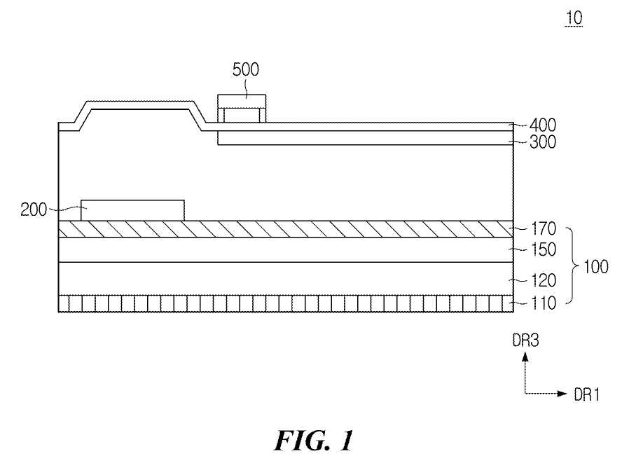

FIG. 1 is a cross-sectional diagram of an embodiment of the present disclosure.

Referring to FIG. 1, the display device 10 according to an embodiment may include a display panel 100, a source substrate portion 200, an inner plate 300, a cover bottom 400, and a control printed circuit board 500.

The display panel 100 may include an encapsulation layer 170, a device layer 150 on the encapsulation layer 170, a cover layer 120 on the device layer 150, and a polarization layer 110 on the cover layer 120, and the display panel 100 may include an organic light emitting display panel, but the embodiments of the present disclosure is not limited thereto.

However, FIG. 1 is a drawing in which the top and bottom of the display panel 100 are reversed, and hereinafter, the disclosure will be described centering on the display panel 100 which is upside down. Therefore, terms such as “upper”, “an upper part”, “below”, “an upper surface” or “a lower surface” are of a relative concept.

In the embodiments, a first direction DR1 and a second direction DR2 are directions different from each other and intersecting each other, and for example, represent directions intersecting perpendicularly in a plan view. A third direction DR3 is a direction intersecting a plane on which the first direction DR1 and the second direction DR2 are placed, and represents, for example, a direction intersecting both the first direction DR1 and the second direction DR2 perpendicularly. In FIG. 1, the first direction DR1 may be the same as an extension direction of short sides of the display panel 100, the second direction DR2 may be the same as an extension direction of long sides of the display panel 100, and the third direction DR3 may be the same as a stacking direction of the display panel 100, the source substrate portion 200, the inner plate 300, the cover bottom 400, and the control printed circuit board 500. However, the direction mentioned by the embodiment should be understood as a relative direction, and the embodiment is not limited to the mentioned direction.

The display panel 100 may have a rectangular shape which includes short sides extending along the first direction DR1 and long sides extending along the second direction DR2. However, the shape of the display panel 100 is not limited thereto, and may be a square shape, a circular shape, an oval shape, or other polygonal shape. Hereinafter, for convenience of description, the disclosure will be described centering on an assumption that the display panel 100 has a rectangular shape. An edge of the display panel 100 may have an angular shape, or a circular shape.

The polarization layer 110 may serve to reduce reflection of external light on a rear surface (based on FIG. 1) of the display device 10, and an upper surface of the polarization layer 110 may face a lower surface of the cover layer 120.

The cover layer 120 may be disposed on the polarization layer 110. The cover layer 120 may be disposed below the device layer 150 and may protect the device layer 150. The lower surface of the cover layer 120 may face the upper surface of the polarization layer 110, and an upper surface of the cover layer 120 may face a lower surface of the device layer 150. The cover layer 120 may be formed of a rigid material including glass or quartz, or a plastic material. A heat conductivity of the cover layer 120 may be lower than a heat conductivity of the encapsulation layer 170. For example, the heat conductivity of the cover layer 120 may be about 0.75W/mK, may be higher than the heat conductivity of the encapsulation layer 170, and thus, heat generated from the device layer 150 may be better transferred to the encapsulation layer 170, rather than to the cover layer 120.

The device layer 150 may be disposed on the cover layer 120. Though not illustrated, the device layer 150 may include a first electrode, an organic layer, and a second electrode. The first electrode may serve as an anode, and the second electrode may serve as a cathode.

The first electrode may include a metal material having a high reflectance such as a stacked structure of aluminum (Al) and titanium (Ti)(Ti/Al/Ti), a stacked structure of aluminum (Al) and indium tin oxide (ITO)(ITO/Al/ITO), and a stacked structure of silver (Ag) and indium tin oxide (ITO)(ITO/Ag/ITO), and an APC alloy, and may consist of a single layer or multiple layers, but the embodiments of the present disclosure are not limited thereto.

The organic layer may include one or more light emitting structures (or light emitting elements or an element) stacked on the first electrode in the order of a hole transfer layer and an electron transfer layer, or in the reverse order. For example, the hole transfer layer may include a hole transport layer, a hole injection layer, an electron blocking layer, a P-type electric charge generation layer or the like, but the embodiments of the present disclosure are not limited thereto. For example, the electron transfer layer may include an electron transport layer, an electron injection layer, a hole blocking layer, an N-type electric charge generation layer or the like, but the embodiments of the present disclosure are not limited thereto.

The organic layer may include an organic light emitting layer. In some embodiments, the organic layer may be replaced with an inorganic light emitting layer, a quantum dot light emitting layer, a micro light emitting diode, a micro-mini light emitting diode and the like, but the embodiments of the present disclosure are not limited thereto. For example, the organic layer of the display panel 100 according to an embodiment of the present disclosure may include an organic light emitting layer, and the organic layer may include a red light emitting layer, a green light emitting layer, and a blue light emitting layer. The organic layer may further include a white light emitting layer, but the embodiments of the present disclosure are not limited thereto.

When the display device 10 is used for a long time, heat may be generated from the organic layer of the device layer 150, and the encapsulation layer 170 having a higher heat conductivity than that of the device layer 150 may be disposed on an upper side of the device layer 150 so as to dissipate the heat.

The second electrode may include a transparent conductive material or metal such as ITO (Indium Tin Oxide) or IZO (Indium Zinc Oxide) through which the visible light is transmitted, but the embodiments of the present disclosure are not limited thereto. For example, the first electrode may serve as the cathode, and the second electrode may serve as the anode.

The encapsulation layer 170 may be disposed on the device layer 150. The encapsulation layer 170 may include metal such as aluminum (Al), iron (Fe), and nickel (Ni), and may include an alloy made of different kinds of metals. In addition, the encapsulation layer 170 may include stainless steel such as invar or steel use stainless (SUS).

The heat conductivity of the encapsulation layer 170 may be higher than a heat conductivity of the device layer 150. For example, the heat conductivity of the encapsulation layer 170 may be about 16W/mk, and the heat conductivity of the device layer may be lower than about 16W/mK, and heat generated from the device layer 150 may be transferred to the encapsulation layer 170.

The heat generated from the device layer 150 of the display panel 100 due to operation of the display device 10 may be transferred to the encapsulation layer 170 through conduction, may be dissipated to the outside of the display panel 100 through convection or radiation between the encapsulation layer 170 and the cover bottom 400, or may be dissipated to the outside through convection or radiation through the inner plate 300. Therefore, deterioration of the device layer 150 of the display panel 100 may be prevented, and a use lifespan of the device layer 150 may be improved.

Although it is illustrated that the encapsulation layer 170 is disposed directly on the device layer 150 in the figure, at least one insulation layer or at least one transistor may be disposed between the encapsulation layer 170 and the device layer 150.

In FIG. 1, the polarization layer 110, the cover layer 120, the device layer 150, and the encapsulation layer 170 are illustrated to be in contact with each other, but an adhesive layer may be further disposed therebetween. However, the embodiments of the present disclosure are not limited thereto.

The source substrate portion 200 may be disposed on the encapsulation layer 170. The source substrate portion 200 may provide the display panel 100 with a signal for driving the display panel 100 of the display device 10. The source substrate portion 200 may include at least one driver chip. The driver chip is well known in this technical field, and thus, detailed description of a function of the driver chip will be omitted.

The cover bottom 400 may support and protect the display panel 100 and the source substrate portion 200. The cover bottom 400 may be formed in a shape corresponding to a planar shape of the display panel 100. However, in other embodiments of the present disclosure, the cover bottom 400 may cover a rear surface and a side surface of the display device 10. The cover bottom 400 may be formed of a material with a high heat conductivity while having rigidity, and may be formed of a metal material or a plastic material such as aluminum (Al), copper (Cu), zinc (Zn), silver (Ag), gold (Au), iron (Fe), steel use stainless (SUS), or Invar.

The inner plate 300 may be disposed between the cover bottom 400 and the display panel 100, and an upper surface of the inner plate 300 may directly be in contact with a lower surface of the cover bottom 400. When heat generated from the device layer 150 and the source substrate portion 200 is dissipated between the cover bottom 400 and the display panel 100, the heat may be transferred to the inner plate 300 through convection, or radiation, and the heat transferred to the inner plate 300 may be dissipated to the outside of the display device 10 through conduction, or radiation. The inner plate 300 may dissipate heat generated from the control printed circuit board 500 through conduction, or radiation, and may make the control printed circuit board 500 and the display panel 100 be not in direct contact with each other, thereby minimizing concentration of heat of the control printed circuit board 500 to the display panel 100.

The control printed circuit board 500 may be disposed on the cover bottom 400. The control printed circuit board 500 may control the display panel 100 and the source substrate portion 200. The control printed circuit board 500 is well known in this technical field, and thus, detailed description of a function of the control printed circuit board 500 will be omitted.

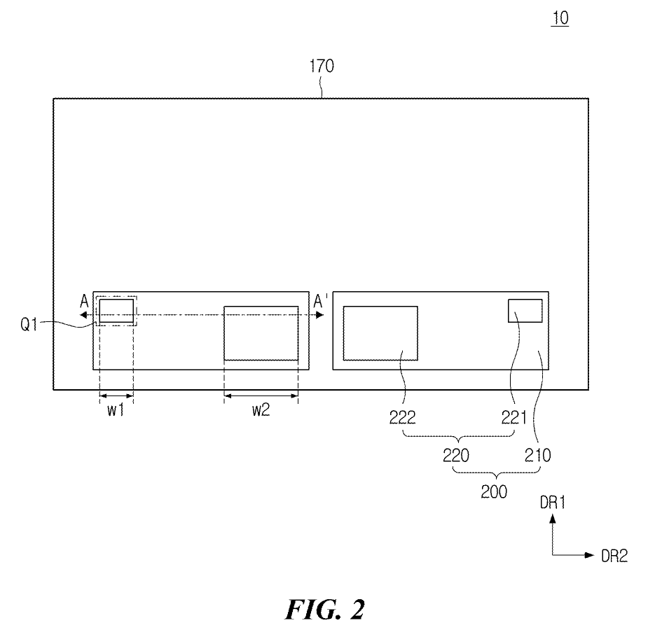

FIG. 2 is a plan diagram of the display device according to FIG. 1.

Referring to FIG. 2, the source substrate portion 200 may be disposed on the encapsulation layer 170, and the source substrate portion 200 may be provided in plural number. The source substrate portion 200 may include a source substrate 210 and a driver chip 220.

The source substrate 210 may be disposed on the encapsulation layer 170, the driver chip 220 may be disposed on the source substrate 210, and the driver chip 220 may be provided in plural number. For example, the driver chip 220 may include a first driver chip 221, and a second driver chip 222, and a width W1 according to the second direction DR2 of the first driver chip 221 may be smaller than a width W2 according to the second direction DR of the second driver chip 222.

It is illustrated that on the source substrate 210, the first driver chip 221 is disposed on an outer side of the display device 10, and the second driver chip 222 is disposed on a center side of the display device 10, however, the embodiments of the present disclosure are not limited thereto. For example, the second driver chip 222 may be disposed on the outer side of the display device 10, and the first driver chip 221 may be disposed on the center side of the display device 10.

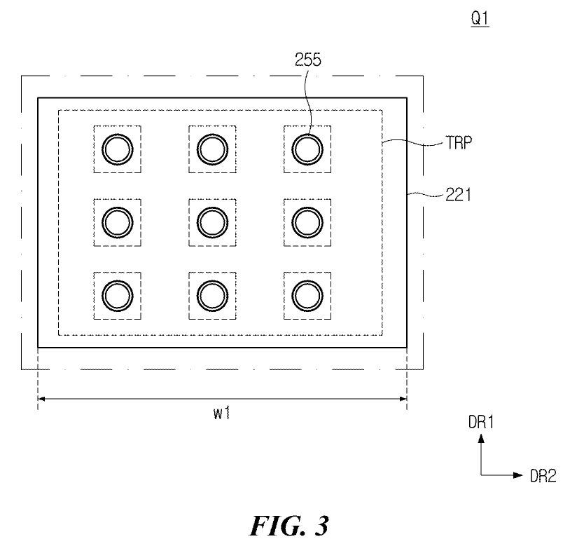

FIG. 3 is a diagram illustrating Q1 region in FIG. 2.

Referring to FIG. 3, the first driver chip 221 may be disposed on a trench TRP, and a heat dissipation portion 255 may be disposed on the first driver chip 221. The trench TRP and the first driver chip 221 may be disposed to overlap each other.

The trench TRP may be provided in plural number, the plurality of trenches TRP may extend in the first direction DR1 or the second direction DR2, the plurality of trenches TRP extending in the first direction DR1 may be spaced apart from each other in the second direction DR2, and the plurality of trenches TRP extending in the second direction DR2 may be spaced apart from each other in the first direction DR1. The trenches TRP extending in the first direction DR1 and the trenches TRP extending in the second direction DR2 may intersect each other, and therefore, the plurality of trenches TRP extending in the first direction DR1 and the second direction DR2 may be disposed in a lattice shape.

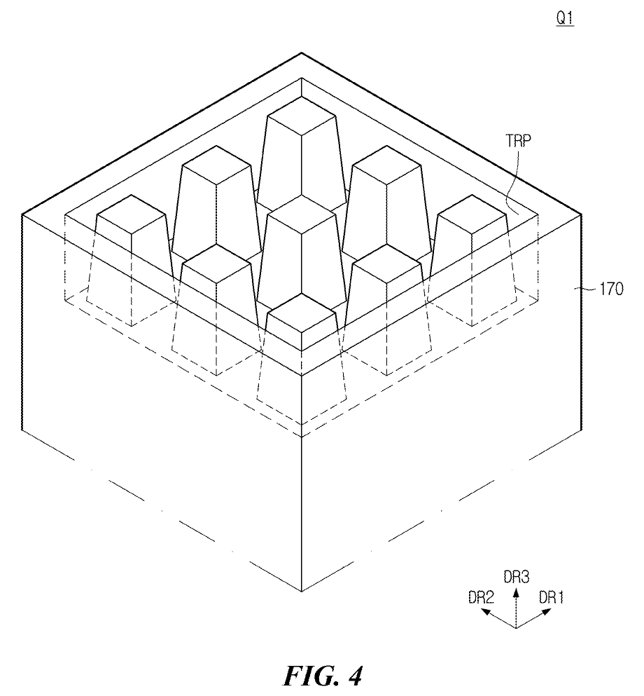

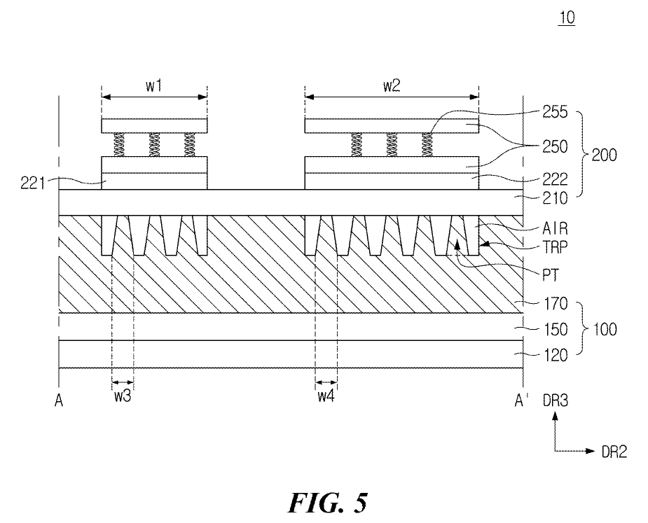

As the trench TRP is formed in a direction recessing the encapsulation layer (refer to 170 in FIG. 1) on a surface of the encapsulation layer, the encapsulation layer (refer to PT in FIG. 5) may be disposed between the plurality of trenches TRP adjacent to each other. Regarding this, further description will be provided referring to FIG. 4 below.

The heat dissipation portion 255 may be provided in plural number, and when viewed based on a plane where the first direction DR1 and the second direction DR2 intersect each other, the heat dissipation portion 255 may be disposed to overlap the encapsulation layer (refer to the protrusion PT in FIG. 5) disposed between the plurality of trenches TRP adjacent to each other. Therefore, the heat generated from the device layer (refer to 150 in FIG. 1) may travel to the encapsulation layer 170 having a higher heat conductivity than that of the device layer (refer to 150 in FIG. 1), and then, may travel to the heat dissipation portion 255 having a higher heat conductivity than that of the device layer (refer to 150 in FIG. 1) as well, and may be discharged to the outside (or a direction toward the cover bottom 400).

FIG. 4 is a perspective diagram illustrating Q1 region in FIG. 2.

Referring to FIG. 4, the encapsulation layer 170 may include a protrusion PT disposed between the plurality of trenches TRP, and the protrusion PT may be provided in plural number. The protrusion PT may have a trapezoidal shape when viewed on a plane (or a cross-section) on which the second direction DR2 and the third direction DR3 intersect each other, and may have a trapezoidal shape as well when viewed on a plane (or a cross-section) on which the first direction and the third direction DR3 intersect each other. A width of an upper surface of the trapezoidal shape may be smaller than a width of a lower surface thereof.

An air may be disposed in the plurality of trenches TRP. Though not illustrated, a source substrate portion (refer to 200 in FIG. 1) may be disposed on the encapsulation layer 170 and the trench TRP. Therefore, a side surface and a lower surface of the air may be surrounded by the trench TRP, and an upper surface thereof may be surrounded by the source substrate portion (refer to 200 in FIG. 1).

FIG. 5 is a cross-sectional diagram taken along A-A′ line in FIG. 2.

Referring to FIG. 5, the trench TRP may be a region recessing the encapsulation layer 170 in a downward direction (for example, another side of the third direction DR3) from an upper surface of the encapsulation layer 170. The trench TRP may partially recess the encapsulation layer 170 in a thickness direction. The trench TRP is disposed between the protrusions PT which will be described below, and thus, may be designed in consideration of a shape of the protrusion PT, and may have, for example, a reversed trapezoidal shape. Each of the plurality of protrusions PT may be spaced apart between the plurality of trenches TRP.

The plurality of protrusions PT and the plurality of trenches TRP which overlap the first driver chip 221 may be disposed below the first driver chip 221, and the plurality of protrusions PT and the plurality of trenches TRP which overlap the second driver chip 222 may be disposed below the second driver chip 222. At this instance, a width W3 of a lower surface of the trapezoid of the plurality of protrusions PT disposed below the first driver chip 221 may be the same as a width W4 of a lower surface of the trapezoid of the plurality of protrusions PT disposed below the second driver chip 222. As described above, the protrusion PT has a trapezoidal shape, and thus, the widths W3 and W4 of each protrusion PT may be tapered toward an upward direction (for example, one side of the third direction DR3).

The air AIR may be disposed in the plurality of trenches TRP. A heat conductivity of the air AIR may be lower than those of the encapsulation layer 170 and the source substrate 210. For example, the heat conductivity of the air AIR may be about 0.003W/mK, and thus, heat may scarcely travel from the encapsulation layer 170 or the source substrate 210 to the air AIR.

A heat dissipation substrate 250 may be disposed on the first driver chip 221 and the second driver chip 222. The heat dissipation substrate 250 may be provided in plural number, and each of the plurality of heat dissipation substrates 250 may overlap the first driver chip 221 and the second driver chip 222.

The heat dissipation substrate 250 may include a material having a higher heat conductivity than that of the device layer 150, and for example, may include a metal material, but the embodiments of the present disclosure are not limited thereto. As the heat conductivity of the heat dissipation substrate 250 is higher than that of the device layer 150, heat generated from the device layer 150 may be transferred to a side of the heat dissipation substrate 250 due to conduction, and may be discharged to the outside through conduction, convection, or radiation. Heat generated from the source substrate 210 and the driver chips 221 and 222 may be transferred to the side of the heat dissipation substrate 250 due to conduction, and may be discharged to the outside through conduction.

The heat dissipation portion 255 may be disposed on the heat dissipation substrate 250. The heat dissipation portion 255 may be provided in plural number, and each of the plurality of heat dissipation portions 255 may overlap the first driver chip 221 and the second driver chip 222. A quantity of the plurality of heat dissipation portions 255 overlapping the first driver chip 221 may be the same as a quantity of the plurality of heat dissipation portions 255 overlapping the second driver chip 222. The plurality of heat dissipation portions 255 may overlap the plurality of protrusions PT.

The heat dissipation substrate 250 may be disposed additionally on the heat dissipation portion 255, but the embodiments of the present disclosure are not limited thereto. When the heat dissipation substrate 250 is disposed additionally on the heat dissipation portion 255, it may have a structure in which a the plurality of the heat dissipation portions 255 are sandwiched between the heat dissipation portions 255 disposed on an upper side and a lower side.

The heat dissipation portions 255 may include a material having a higher heat conductivity than that of the device layer 150, and for example, may include a metal material, but the embodiments of the present disclosure are not limited thereto. As each of the heat conductivity of the heat dissipation portions 255, the heat dissipation substrate 250, the encapsulation layer 170, and the protrusion PT is higher than that of the device layer 150, heat generated from the device layer 150 may be transferred to the protrusion PT, and to the heat dissipation substrate 250 and the heat dissipation portion 255 which overlap the protrusion PT, and may be discharged to the outside. Heat generated from the source substrate 210 and the driver chips 221 and 222 may be transferred to the heat dissipation substrate 250 and the heat dissipation portion 255, and may be discharged to the outside.

The heat dissipation portion 255 may have a material having elasticity. For example, the heat dissipation portion 255 may include a spring or a spring coil, but the embodiments of the present disclosure are not limited thereto, and the heat dissipation portion 255 may include a member if the member has elasticity. As the heat dissipation portion 255 has elasticity, when an impact is applied to the display device 10 from the outside, the heat dissipation portion 255 may ease the impact generated between the heat dissipation portion 255 and the cover bottom (refer to 400 in FIG. 1). When the heat dissipation portion 255 includes a spring coil, an area to which heat is dissipated through the heat dissipation portion 255 may increase, and heat dissipating efficiency may increase.

A conventional large-scale display device has used a method for dissipating heat using radiation or convection in a direction of the cover bottom on a lower part so as to solve a problem of high heat because of an increased heat amount in the source substrate portion positioned on the lower part. In order to ensure a more effective heat dissipation, a heat dissipation function by conduction has been attempted additionally by attaching a conductive heat dissipation portion utilized by other industries, however, in such a case, the heat dissipation portion has to be designed long in a thickness direction because a wider surface area of the heat dissipation portion is required, but this causes a gap between the heat dissipation portion and the cover bottom to be narrowed. Therefore, there is a problem in that a physical damage in the heat dissipation portion may easily occur by an impact applied from the outside, and when widening the gap between the heat dissipation portion and the cover bottom so as to make up for such a problem, a thickness of the display device becomes thicker. Accordingly, in many cases, the conventional large scale display device has not applied the conductive heat dissipation portion.

When the heat dissipation portion 255 according to an embodiment includes a material having elasticity, there is an effect that a physical damage in the heat dissipation portion 255 is prevented even if an impact between the heat dissipation portion 255 and the cover bottom 400 is generated due to the impact applied from the outside.

In addition, without widening the gap between the heat dissipation portion 255 and the cover bottom 400, there is an effect that the thickness of the display device 10 can be made slim. In addition, when the heat dissipation portion 255 includes a material having elasticity, there is an effect that the thickness of the display device 10 is made slim because the thickness of the heat dissipation portion 255 alone may become smaller compared to that of the conventional heat dissipation portion.

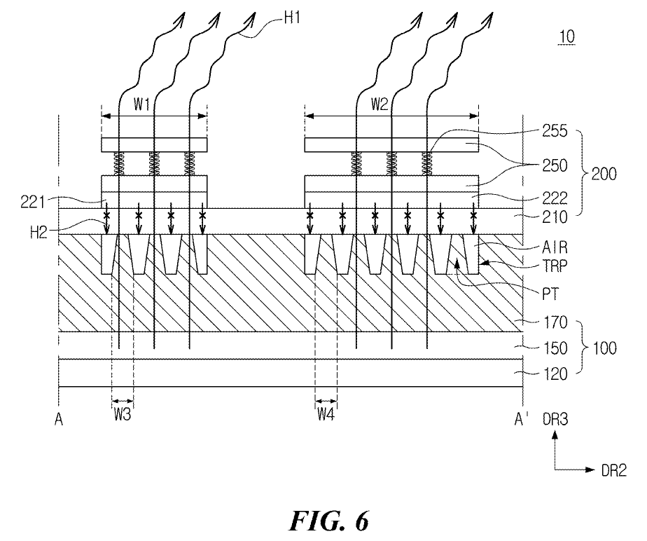

FIG. 6 is a schematic diagram illustrating a travel path of heat in the display device according to an embodiment.

Referring to FIG. 6, heat H1 generated from the device layer 150 may be better transferred to the encapsulation layer 170 having a higher heat conductivity than that of the cover layer 120. Heat scarcely travels to the air AIR having a heat conductivity much lower than that of the encapsulation layer 170, and thus, most of heat H1 transferred to the encapsulation layer 170 may be transferred to a side of the source substrate 210 along the protrusion PT. The heat H1 transferred to the source substrate 210 may travel along the heat dissipation portion 255 overlapping the driver chip 220, the heat dissipation substrate 250, and the protrusion PT by conduction, and then, may be discharged to the outside (or toward the cover bottom 400 side). The discharged heat H1 may be completely discharged to the outside of the display device 10 by conduction, convection, or radiation between the driver chips 221 and 222 and the cover bottom 400.

Heat H2 generated from the driver chip 220 and/or the source substrate 210 may be transferred to the encapsulation layer 170 having a higher heat conductivity. As the heat H2 transferred to the encapsulation layer 170 is prevented from traveling to the air AIR having a lower heat conductivity than that of the encapsulation layer 170, the heat H2 cannot travel to the device layer 150 through the encapsulation layer 170, and may be discharged to the outside (or in a direction of the cover bottom 400) through the heat dissipation substrate 250 and the heat dissipation portion 255 having a higher heat conductivity than that of the air AIR. The heat H2 discharged to the outside may be completely discharged to the outside of the display device 10 by conduction, convection, or radiation between the driver chips 221 and 222 and the cover bottom 400. At this instance, as described above, the protrusion PT has the trapezoidal shape, and thus, the widths W3 and W4 of each protrusion PT may be tapered toward the upward direction (for example, one side of the third direction DR3). Therefore, in an area in contact with the source substrate 210, the widths W3 and W4 of each protrusion PT may be smaller than those in an area not in contact with the source substrate 210.

Therefore, both of the heat H1 generated from the device layer 150 and the heat H2 generated from the driver chip 220 and the source substrate 210 may be transferred to the side of the heat dissipation portion 255, rather than to a side of the device layer 150, and may be discharged to a side of the cover bottom (refer to 400 in FIG. 1).

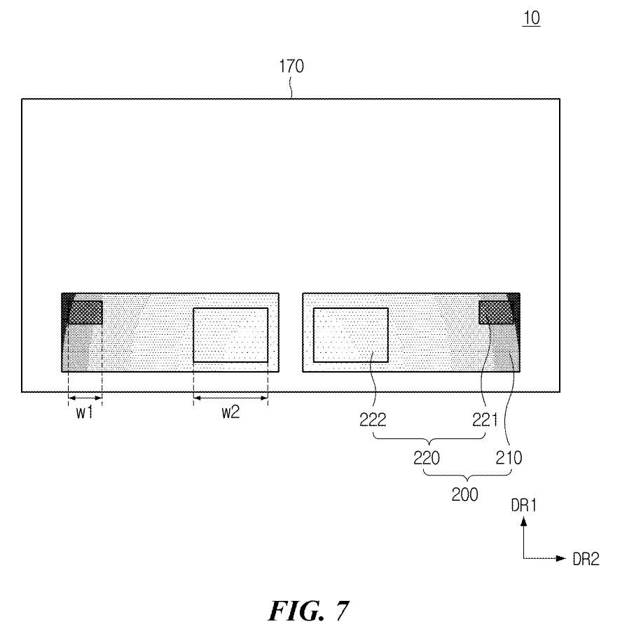

FIG. 7 is a schematic diagram illustrating a temperature gradient of a display device according to an embodiment.

Referring to FIG. 7, based on a plane on which the first direction DR1 and the second direction DR2 intersect, an area of the first driver chip 221 may be smaller than an area of the second driver chip 222, and a temperature of the first driver chip 221 may be higher than a temperature of the second driver chip 222. Therefore, when the first driver chip 221 is disposed on an outer side of the display device 10 and the second driver chip 222 is disposed at a center of the display device 10 in a plan view, a temperature of the outer side of the display device 10 may be higher than that of the center.

Though not illustrated, a heat generation reaction may occur in the device layer (refer to 1 50 in FIG. 1) disposed below the encapsulation layer 170 (for example, in the third direction DR3), and a heat generation amount of the device layer (refer to 150 in FIG. 1) may be smaller than those of the driver chips 221 and 222. Therefore, when the driver chips 221 and 222 are disposed on a lower side of the display device 10 in a plan view, a temperature of the lower side of the display device 10 may be higher than that of an upper side and that of the center of the display device 10.

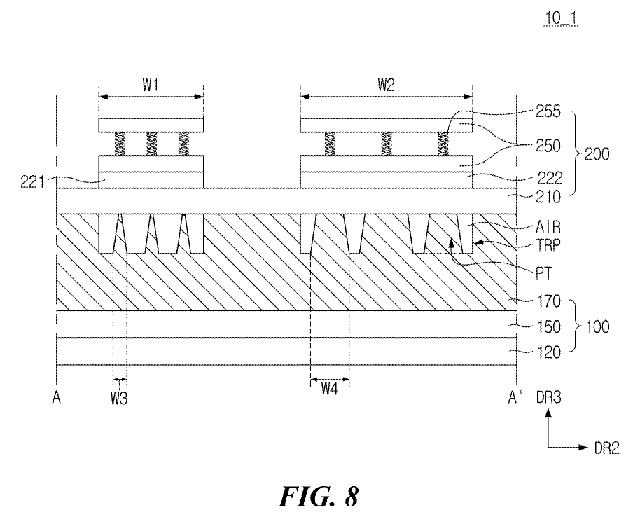

FIG. 8 is a cross-sectional diagram of a display device according to another embodiment.

Referring to FIG. 8, the plurality of trenches TRP and the plurality of protrusions PT overlapping the first driver chip 221 may be disposed below the first driver chip 221, and the plurality of trenches TRP and the plurality of protrusions PT overlapping the second driver chip 222 may be disposed below the second driver chip 222. At this instance, the width W3 of the lower surface of the trapezoid of the plurality of protrusions PT disposed below the first driver chip 221 may be smaller than the width W4 of the lower surface of a trapezoid of the plurality of protrusions PT disposed below the second driver chip 222, and a width of an upper surface of the trapezoid of the plurality of protrusions PT overlapping the first driver chip 221 may be smaller than a width of an upper surface of the trapezoid of the plurality of protrusions PT overlapping the second driver chip 222.

The trench TRP is disposed between the protrusions PT, and based on a plan view in which the second direction DR2 and the third direction DR3 intersect, an area of each of the plurality of trenches TRP disposed below the first driver chip 221 may be wider than an area of each of the plurality of trenches TRP disposed below the second driver chip 222.

In order to dissipate heat generated from the first driver chip 221 effectively, heat is typically discharged to the outside through the heat dissipation substrate 250 and the heat dissipation portion 255 without being transferred to the encapsulation layer 170, and thus, the area of the protrusion PT overlapping the first driver chip 221 may decrease, while an area of the air AIR overlapping the first driver chip 221 may increase.

On contrary, a relatively smaller amount of heat may be generated in the second driver chip 222 than that generated in the first driver chip 221, and thus, the area of the protrusion PT overlapping the second driver chip 222 may increase, while the area of the air AIR overlapping the second driver chip 222 may decrease. It is possible to stabilize the structure and increase a dissipation amount of heat generated from the device layer (refer to 150 in FIG. 1) by increasing the overlapping area between the protrusion PT and the source substrate (refer to 210 in FIG. 1) overlapping the second driver chip 222.

As described above, by changing areas of the protrusion PT and the air AIR overlapping the driver chips 221 and 222 in consideration of the dissipation amount of heat of the driver chips 221 and 222, it is possible to adjust efficiency of heat dissipation of the device layer (refer to 150 in FIG. 1) and the driver chips 221 and 222. In addition, by increasing the dissipation amount of heat in a position where a temperature is high on a surface of the display device 10, it is possible to create a balance of the temperature on the surface of the display device 10.

Description on other components has been provided in detail referring to FIG. 5, and will be omitted.

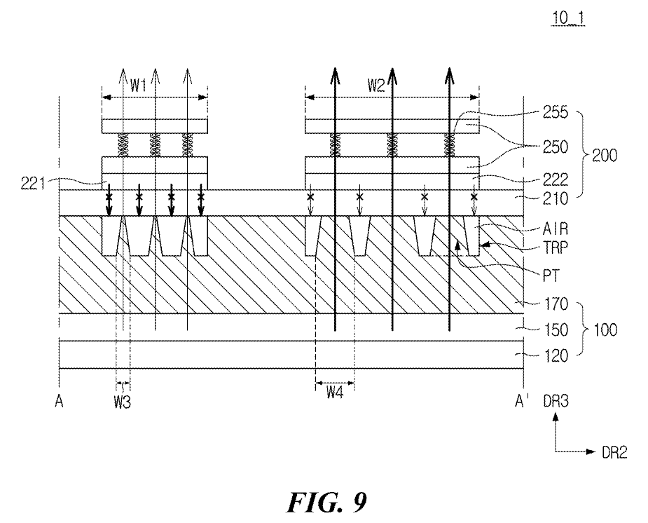

FIG. 9 is a schematic diagram illustrating a travel path of heat in the display device according to FIG. 8.

Referring to FIG. 9, based on a plan view in which the second direction DR2 and the third direction DR3 intersect, as an area of the trench TRP overlapping the first driver chip 221 becomes greater than an area of the trench overlapping the second driver chip 222, travel of heat generated from the first driver chip 221 to the encapsulation layer 170 may be relatively further restricted than travel of the heat generated from the second driver chip 222 to the encapsulation layer 170.

On contrary, as the area of the protrusion PT overlapping the first driver chip 221 becomes smaller than the area of the protrusion PT overlapping the second driver chip 222, the dissipation amount of heat generated from the device layer 150 through the protrusion PT may become greater in the protrusion PT overlapping the second driver chip 222 than that in the protrusion overlapping the first driver chip 221.

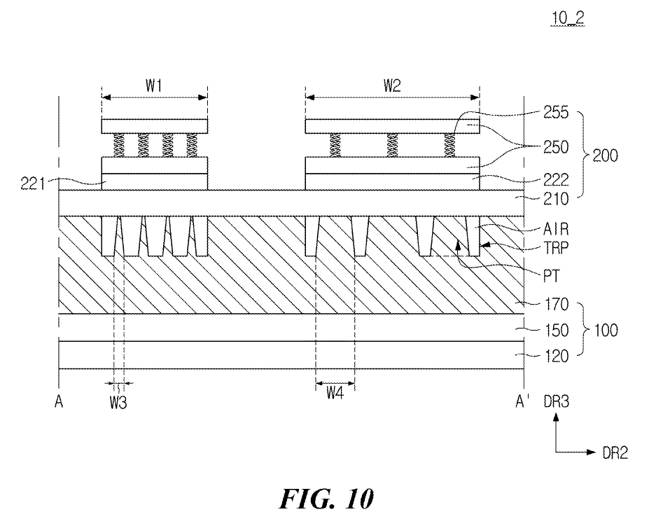

FIG. 10 is a cross-sectional diagram of a display device according to still another embodiment.

Referring to FIG. 10, the plurality of trenches TRP and the plurality of protrusions PT may be disposed below the first driver chip 221 and the second driver chip 222, and the plurality of heat dissipation portions 255 may be disposed on the first driver chip 221 and the second driver chip 222. An amount of the plurality of trenches TRP, the protrusions PT, and the heat dissipation portions 255 overlapping the first driver chip 221 may be greater than an amount of the plurality of trenches TRP, the protrusions PT, and the heat dissipation portions 255 overlapping the second driver chip 222.

Based on a plan view in which the second direction DR2 and the third direction DR3 intersect, a sum of each of areas of the plurality of trenches TRP overlapping the first driver chip 221 may be greater than a sum of each of areas of the plurality of trenches TRP overlapping the second driver chip 222.

Description on other components has been provided in detail referring to FIGS. 5 and 8, and will be omitted.

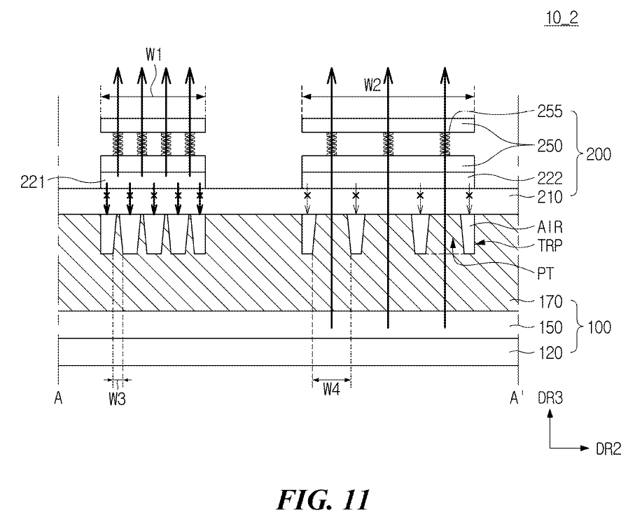

FIG. 11 is a schematic diagram illustrating a travel path of heat in the display device according to FIG. 10.

Referring to FIG. 11, based on a plan view in which the second direction DR2 and the third direction DR3 intersect, as the sum of each of areas of the plurality of trenches TRP overlapping the first driver chip 221 is greater than the sum of each of areas of the plurality of trenches TRP overlapping the second driver chip 222, travel of heat generated from the first driver chip 221 may be relatively further restricted than travel of the heat generated from the second driver chip 222 to the encapsulation layer 170.

As a sum of each of areas of the plurality of protrusions PT overlapping the first driver chip 221 gets smaller than a sum of each of areas of the protrusions PT overlapping the second driver chip 222, the dissipation amount of heat generated from the device layer 150 through the protrusion PT may increase more in the protrusion PT overlapping the second driver chip 222 than that in the protrusion PT overlapping the first driver chip 221.

Heat transferred from the device layer 150 to the first driver chip 221, and/or heat generated from the first driver chip 221 may be discharged to the outside through the plurality of heat dissipation portions 255.

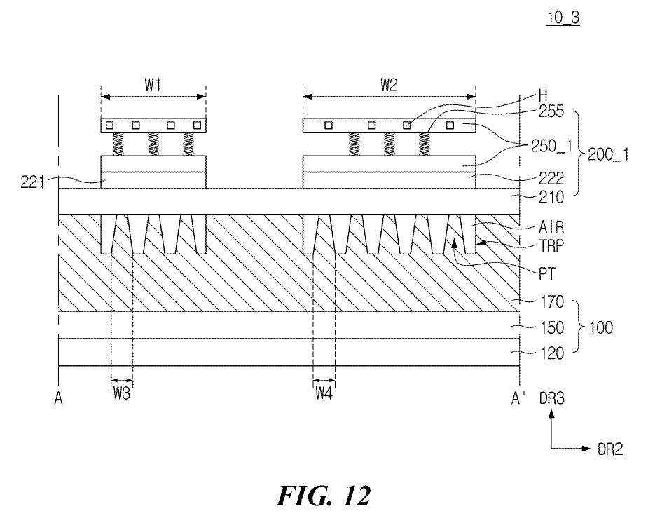

FIG. 12 is a cross-sectional diagram of a display device according to still another embodiment.

Referring to FIG. 12, a heat dissipation substrate 250_1 may be provided in plural number, and the plurality of heat dissipation substrates 250_1 may be disposed in a sandwich shape with the heat dissipation portion 255 interposed therebetween. The heat dissipation substrate 250_1 disposed on the heat dissipation portion 255 may have a hole H, and the hole H may be disposed not to overlap the heat dissipation portion 255.

Heat transferred between the display panel 100 and the cover bottom (refer to 40 in FIG. 1) through the heat dissipation portion 255 and the heat dissipation substrate 250_1 is discharged to the outside through convection or radiation, and at this instance, it is possible to increase heat dissipating efficiency through convection heat transfer generated in the hole H.

Description on other components has been provided in detail referring to FIG. 5, and will be omitted.

The display device according to various embodiments of the present disclosure may be described as below.

One embodiment is a display device, including: a display panel comprising a cover layer, a device layer on the cover layer, and an encapsulation layer on the device layer; a source substrate on the display panel; and at least one driver chip on the source substrate, and the encapsulation layer may include at least one trench configured to recess a surface of the encapsulation layer, and the at least one trench may overlap the driver chip.

In a display device according to various embodiments of the present disclosure, an air may be disposed in the at least one trench.

In a display device according to various embodiments of the present disclosure, the air may be surrounded by the source substrate and the trench.

In a display device according to various embodiments of the present disclosure, the display device may further include: at least one protrusion, and the at least one protrusion may be disposed between the trenches adjacent to each other.

In a display device according to various embodiments of the present disclosure, a width of an upper surface of the at least one protrusion may be smaller than a width of a lower surface thereof.

In a display device according to various embodiments of the present disclosure, the display device may further include: at least one heat dissipation portion, and the at least one heat dissipation portion may be disposed on the driver chip.

In a display device according to various embodiments of the present disclosure, the at least one heat dissipation portion may have elasticity.

In a display device according to various embodiments of the present disclosure, the at least one heat dissipation portion may overlap the at least one protrusion in a plan view.

In a display device according to various embodiments of the present disclosure, the encapsulation layer may include a metal material.

In a display device according to various embodiments of the present disclosure, a heat conductivity of the encapsulation layer may be higher than a heat conductivity of the cover layer.

In a display device according to various embodiments of the present disclosure, the at least one driver chip may include a first driver chip and a second driver chip, and a width of the first driver chip may be smaller than a width of the second driver chip.

In a display device according to various embodiments of the present disclosure, a temperature generated from the first driver chip may be higher than a temperature generated from the second driver chip.

In a display device according to various embodiments of the present disclosure, the display device may further include: at least one protrusion, and the at least one protrusion may be disposed between the trenches adjacent to each other, and a width of the protrusion disposed below

the first driver chip may be smaller than a width of the protrusion disposed below the second driver chip.

In a display device according to various embodiments of the present disclosure, the display device may further include: at least one protrusion, and the at least one protrusion is disposed between the trenches adjacent to each other, and an area ratio of the trench in an area overlapping the first driver chip may be greater than an area ratio of the trench in an area overlapping the second driver chip in a plan view.

Another embodiment is a display device, including: a display panel comprising a device layer and an encapsulation layer on the device layer; a source substrate on the display panel; and a source substrate portion comprising at least one driver chip on the source substrate; and a plurality of heat dissipation portions on the at least one driver chip, and the heat dissipation portion may have elasticity.

In a display device according to various embodiments of the present disclosure, the encapsulation layer may include a plurality of trenches configured to recess a surface of the encapsulation layer and a protrusion between the trenches adjacent to each other, and the plurality of trenches and the protrusion may overlap the driver chip.

In a display device according to various embodiments of the present disclosure, an air may be disposed in the plurality of trenches.

In a display device according to various embodiments of the present disclosure, the heat dissipation portion may overlap the protrusion in a plan view.

In a display device according to various embodiments of the present disclosure, a width of an upper surface of the protrusion may be smaller than a width of a lower surface of the protrusion.

The embodiments of the present disclosure have been described with reference to accompanying drawings. Those of ordinary skill in the art will recognize that the present disclosure may be embodied in other specific forms without departing from its technical idea or essential characteristics. The described embodiments are to be considered in all respects only as illustrative and not restrictive. The scope of the present disclosure is therefore indicated by the appended claims rather than by the foregoing description. All changes which come within meaning and range of equivalency of the claims are to be embraced within the scope of the present disclosure.

### REFERENCE NUMERALS

10: display device

100: display panel

110: polarization layer

120: cover layer

150: device layer

170: encapsulation layer

200: source substrate portion

210: source substrate

220: driver chip

250: heat dissipation substrate

255: heat dissipation portion

300: inner plate

400: cover bottom

500: control printed circuit board

TRP: trench

PT: protrusion

H: hole

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a cover layer, a device layer on the cover layer, and an encapsulation layer on the device layer;
a source substrate on the display panel; and
at least one driver chip on the source substrate,
wherein the encapsulation layer includes at least one trench configured to recess a surface of the encapsulation layer, and
wherein the at least one trench overlaps the at least one driver chip.

2. The display device of claim 1,
wherein an air is disposed in the at least one trench.

3. The display device of claim 2,
wherein the air is surrounded by the source substrate and the at least one trench.

4. The display device of claim 1, further comprising:
at least one protrusion,
wherein the at least one protrusion is disposed adjacent to the at least one trench.

5. The display device of claim 4,
wherein a width of an upper surface of the at least one protrusion is smaller than a width of a lower surface thereof.

6. The display device of claim 4, further comprising:
at least one heat dissipation portion,
wherein the at least one heat dissipation portion is on the at least one driver chip.

7. The display device of claim 6,
wherein the at least one heat dissipation portion has elasticity.

8. The display device of claim 6,
wherein the at least one heat dissipation portion overlaps the at least one protrusion in a plan view.

9. The display device of claim 1,
wherein the encapsulation layer comprises a metal material.

10. The display device of claim 1,
wherein a heat conductivity of the encapsulation layer is higher than a heat conductivity of the cover layer.

11. The display device of claim 1,
wherein the at least one driver chip comprises a first driver chip and a second driver chip, and
wherein a width of the first driver chip is smaller than a width of the second driver chip.

12. The display device of claim 11,
wherein a temperature of the first driver chip during operation is higher than a temperature of the second driver chip during operation.

13. The display device of claim 11, further comprising:
at least one protrusion,
wherein the at least one protrusion is disposed adjacent to the at least one trench, and
wherein a width of the protrusion disposed below the first driver chip is smaller than a width of the protrusion disposed below the second driver chip.

14. The display device of claim 11, further comprising:
at least one protrusion,
wherein the at least one protrusion is disposed adjacent to the at least one trench, and
wherein an area ratio of the at least one trench in an area overlapping the first driver chip is greater than an area ratio of the at least one trench in an area overlapping the second driver chip in a plan view.

15. A display device, comprising:
a display panel including a device layer and an encapsulation layer on the device layer;
a source substrate on the display panel; and
a source substrate portion including at least one driver chip on the source substrate; and
a plurality of heat dissipation portions on the at least one driver chip,
wherein each of the plurality of heat dissipation portions has elasticity.

16. The display device of claim 15,
wherein the encapsulation layer comprises a plurality of trenches configured to recess a surface of the encapsulation layer and a protrusion between adjacent ones of the plurality of trenches, and
wherein the plurality of trenches and the protrusion overlap the at least one driver chip.

17. The display device of claim 16, further comprising:
an air disposed in the plurality of trenches.

18. The display device of claim 17,
wherein each of the plurality of heat dissipation portions overlaps the protrusion in a plan view.

19. The display device of claim 17,
wherein a width of an upper surface of the protrusion is smaller than a width of a lower surface of the protrusion.
